(19) United States
(12) Patent Application Publication
(10) Pub. No.: US 2026/0266897 A1
(43) Pub. Date: Sep. 10, 2026

(54) PROBER

(71) Applicant: Tokyo Seimitsu Co., Ltd., Tokyo (JP)

(72) Inventor: Tetsuo YOSHIDA, Tokyo (JP)

(21) Appl. No.: 19/168,186

(22) PCT Filed: Feb. 21, 2024
(86) PCT No.: PCT/JP2024/006282

§ 371 Date: Sep. 23, 2025

(30) Foreign Application Priority Data
Mar. 30, 2023 (JP) 2023-055172

(51) Int. Cl. G01R 31/28; G01R 1/073; H04N 23/695; H04N 23/90

(52) U.S. Cl. CPC G01R 31/2887; G01R 1/07342; H04N 23/695; H04N 23/90

(57) ABSTRACT

A prober 10 including a wafer chuck 16 holding a wafer W, a probe card 24 having a probe 25 on a surface facing the wafer chuck 16, movement mechanisms 13, 14, and 15 that move the wafer chuck 16 relative to the probe card 24, a probe imaging unit 18 that has two cameras 18_{L} and 18_{R} and takes images of a probe 25 by the two cameras 18_{L} and 18_{R}, and a probe position detector 27 that detects a position of a tip T of the probe 25 based on two images I_{L} and I_{R} taken by the two cameras 18_{L} and 18_{R} can quickly detect the position of the tip of the probe.

### FIELD

The present invention relates to a prober that inspects the electric characteristics of semiconductor devices (chips) formed on a wafer, and relates to a prober that can quickly detect the position of the tip of a probe.

### BACKGROUND

The semiconductor manufacturing process has many steps, and various inspections are performed in various manufacturing steps in order to assure quality and improve yield. For example, in a stage in which a plurality of chips including semiconductor devices are formed on a wafer, an electrode pad of each chip is connected to a tester, and power and a test signal are supplied from the tester. A signal output from the semiconductor device formed on each chip is then measured by the tester. This allows the semiconductor device to be electrically inspected for normal operation (wafer level inspection). This wafer level inspection is performed using a prober.

In the wafer level inspection, a probe (stylus) of a probe card installed in the prober is required to be accurately brought into contact with the electrode pad on the chip. For example, a probe device (prober) described in Patent Literature 1 includes an optical device for a stylus (a probe position detection camera) that takes an image of a probe of a probe card from below, detects the tip of the probe by taking an image by a probe position detection camera, and based on the detection result, drives a Z stage of a chuck part that places a wafer to bring the tip of the probe into contact with an electrode pad.

### CITATION LIST

### Patent Literature

Patent Literature 1: Japanese Patent Application Laid-open No. 2004-039752

### SUMMARY

### Technical Problem

However, in the technology described in Patent Literature 1, the probe position detection camera is focused on the tip of the probe by driving the Z stage and moving the probe position detection camera up and down, thus detecting the position of the tip of the probe. Especially when the depth of focus of the probe position detection camera is shallow, the probe position detection camera is required to be focused on the tip of the probe while changing the relative distance between the probe card and the probe position detection camera in small increments to avoid a collision between the probe and the probe position detection camera. This causes a problem in that it takes time to detect the position of the tip of the probe.

The present invention has been made in view of such circumstances, and an object thereof is to provide a prober that can quickly detect the position of the tip of a probe.

### Solution to Problem

A prober according to a first aspect includes a wafer chuck that holds a wafer, a probe card that has a probe on a surface facing the wafer chuck, a movement mechanism that moves the wafer chuck relative to the probe card, a probe imaging unit that has two cameras and takes images of the probe by the two cameras, and a probe position detector that detects a position of a tip of the probe based on two images taken by the two cameras.

In the prober according to the first aspect, the position of the tip of the probe can be detected based on the images taken by the two cameras. Since virtually no time is required for the focusing of the probe position detection camera, the position of the tip of the probe can be quickly detected.

Preferably, imaging optical axes of the two cameras intersect each other. This enables the probe position detector to detect the position of the tip of the probe using relatively easy geometric operations.

More preferably, the two cameras are each a camera configured with a telecentric optical system. Since the two cameras have the telecentric optical system, the size of the tip of the probe in the taken images (imaging magnification) is almost independent of the distance from each of the cameras to the tip and is nearly constant. Therefore, the probe position detector can detect the position of the tip of the probe in a real space with relatively easy operations based on the position of the tip of the probe on the images.

Preferably, the movement mechanism can move the probe imaging unit relative to the probe card.

### Advantageous Effects of Invention

According to the present invention, the position of the tip of the probe can be quickly detected.

### BRIEF DESCRIPTION OF DRAWINGS

FIG. 1 is a schematic configuration diagram of a prober.

FIG. 2 is a configuration diagram of a probe imaging unit.

FIG. 3 is a diagram illustrating the principle of detecting the position of the tip of a probe.

FIG. 4 is a diagram illustrating the principle of detecting the position of the tip of the probe.

FIG. 5 is a diagram illustrating the principle of detecting the position of the tip of the probe.

FIG. 6 is a diagram illustrating the principle of detecting the position of the tip of the probe.

FIG. 7 is a diagram illustrating the principle of detecting the position of the tip of the probe.

FIG. 8 is a diagram illustrating the positional relation between the tip of the probe and optical axes of respective cameras.

FIG. 9 is a diagram illustrating the position of the tip of the probe in fields of view of the respective cameras.

FIG. 10 is a diagram illustrating the calculation of an X coordinate and a Y coordinate of the tip of the probe in a real space.

### DESCRIPTION OF EMBODIMENTS

Preferred embodiments of the present invention will be described below in accordance with the accompanying drawings.

### <Configuration of Wafer Test System>

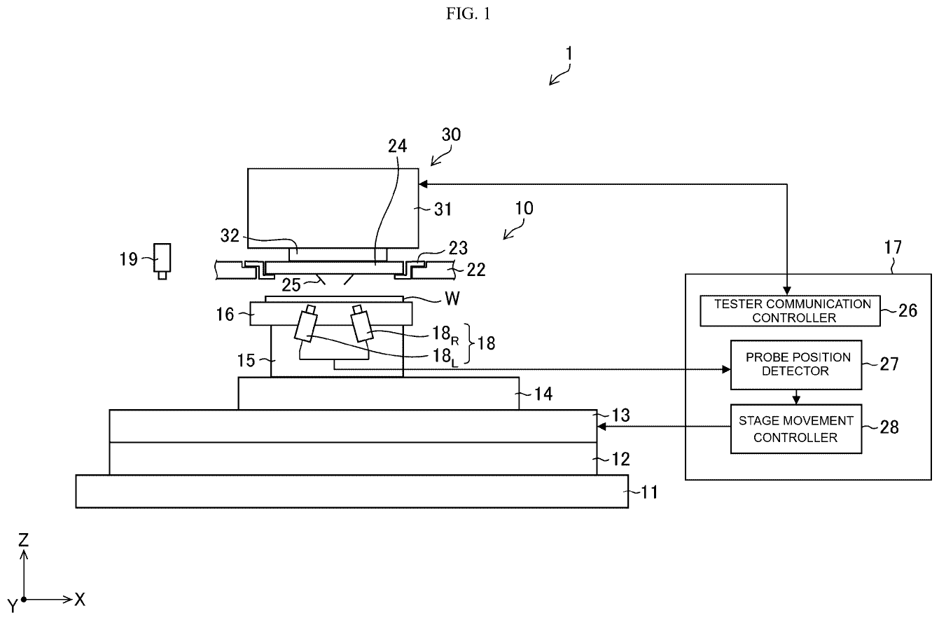

First, a schematic configuration of a wafer test system 1 will be described using FIG. 1. Note that the XYZ axes in the figures are axes orthogonal to each other, with the XY axes being axes parallel to the horizontal direction and the Z axis being an axis orthogonal to the horizontal direction. Hereafter, the upper and the upper surface in the Z-axis direction, which is the vertical direction in the figures, are referred to as “upper” and “upper surface” as appropriate, and the lower and the lower surface in the Z-axis direction are referred to as “lower” and “lower surface” as appropriate.

The wafer test system 1 inspects the electric characteristics of each of a plurality of chips. This wafer test system 1 includes a prober 10 and a tester 30.

The prober 10 brings a probe 25 into contact with an electrode (not illustrated) formed on the surface of each chip (not illustrated) on a wafer W. The tester 30 is electrically connected to the probe 25 and inspects the electric characteristics of each chip.

The prober 10 includes a support base 11, a base 12, a Y stage 13, an X stage 14, a Zθ stage 15, a wafer chuck 16, a controller 17, a probe imaging unit 18, a wafer alignment camera 19, a head stage 22, a card holder 23, and a probe card 24. The Y stage 13, the X stage 14, and the Ze stage 15 correspond to a movement mechanism of the present invention.

The base 12 is fixed to the upper surface of the support base 11. Note that leg members may be used instead of the support base 11, or the support base 11 and the base 12 may be integrally formed.

On the upper surface of the base 12, the Y stage 13 is supported movably in the Y-axis direction via an unillustrated Y movement part. The Y movement part includes a guide rail provided on the upper surface of the base 12 and parallel to the Y axis, a slider provided on the lower surface of the Y stage 13 and engaged with the guide rail, and a drive mechanism such as a motor that moves the Y stage 13 in the Y-axis direction. By driving this Y movement part, the Y stage 13, and the X stage 14, the Zθ stage 15, and the like, which will be described later, are integrally moved in the Y-axis direction on the base 12.

On the upper surface of the Y stage 13, the X stage 14 is supported movably in the X-axis direction via an unillustrated X movement part. The X movement part includes a guide rail provided on the upper surface of the Y stage 13 and parallel to the X axis, a slider provided on the lower surface of the X stage 14 and engaged with the guide rail, and a drive mechanism such as a motor that moves the X stage 14 in the X-axis direction. By driving this X movement part, the X stage 14, and the Zθ stage 15 and the like, which will be described later, are integrally moved in the X-axis direction on the Y stage 13.

On the upper surface of the X stage 14, the Zθ stage 15 is provided. The Zθ stage 15 is provided with an unillustrated Zθ movement part. On the upper surface of the Zθ stage 15, the wafer chuck 16 is held via the unillustrated Ze movement part. The Ze movement part has, for example, a lifting and lowering mechanism that can move the upper surface of the Zθ stage 15 in the Z-axis direction and a rotation mechanism that rotates this upper surface about the axis of the Z axis. Thus, the Ze movement part moves the wafer chuck 16 held on the upper surface of the Zθ stage 15 in the Z-axis direction and rotates it about the axis of the Z axis.

The wafer chuck 16 holds the wafer W from its back side. This wafer chuck 16 is supported by the Y stage 13, the X stage 14, and the Zθ stage 15 previously described movably in the XYZ-axis direction with respect to the base 12, and is supported rotatably about the axis of the Z axis. This can move the wafer W held by the wafer chuck 16 and the probe 25, which will be described later, relative to each other.

The head stage 22, for example, constitutes the top plate of an unillustrated housing of the prober 10, and is supported above the wafer chuck 16 (the wafer W) by an unillustrated pillar or the like. In the central part of the head stage 22, a substantially annular card holder 23 holding the probe card 24 is provided. That is, the head stage 22 holds the probe card 24 via the card holder 23.

The probe card 24 has a plurality of the probes 25. These probes 25 are arranged on the probe card 24 in a pattern corresponding to the arrangement pattern of electrodes of unillustrated respective chips of the wafer W to be inspected.

The probe imaging unit 18 has two cameras 18_{L} and 18_{R} and takes images of the probe 25 using the cameras 18_{L} and 18_{R}. The configuration of the probe imaging unit 18 will be described later in detail.

The wafer alignment camera 19 is supported by an unillustrated pillar provided on the base 12 and takes an image of the chip (not illustrated) of the wafer W held by the wafer chuck 16 from above. Based on the image of the chip taken by this wafer alignment camera 19, the position of the electrode of the chip can be detected.

The controller 17 comprehensively controls the operation of the entire prober 10. The controller 17 includes an arithmetic device such as a personal computer and includes an arithmetic circuit including various processors and memories. Examples of various processors include central processing units (CPUs), graphics processing units (GPUs), application specific integrated circuits (ASICs), and programmable logic devices. Examples of programmable logic devices include simple programmable logic devices (SPLDs), complex programmable logic devices (CPLDs), and field programmable gate arrays (FPGAs).

The various functions of the controller 17 may be implemented by a single processor or implemented by a plurality of processors of the same type or different types. The controller 17 includes, for example, a tester communication controller 26, a probe position detector 27, and a stage movement controller 28 for each function.

The tester communication controller 26 controls communication, including a test signal and control information used for wafer level inspection, between the test head 31 and the prober 10. The communication method may be wired communication or wireless communication.

The probe position detector 27 detects the position of a tip T of the probe 25 based on the images of the probe 25 taken by the two cameras 18_{L} and 18_{R} that constitute the probe imaging unit 18. The detection of the position of the tip T of the probe 25 by the probe position detector 27 will be described later in detail.

The stage movement controller 28 controls the movement of each stage via the unillustrated drive mechanisms provided in the Y stage 13, the X stage 14, and the Zθ stage 15. The stage movement controller 28 moves the Y stage 13, the X stage 14, the Ze stage 15, and the like based on the position of the electrode detected by the wafer alignment camera 19 and the position of the tip T of the probe 25 detected by the probe position detector 27, thereby aligning the probe 25 and the electrode of the chip of the wafer W with each other.

The tester 30 includes a test head 31 and a contact ring 32 provided on the test head 31. The probe card 24 is provided with terminals to be connected to the respective probes 25. The contact ring 32 has spring probes arranged in an arrangement pattern that can come into contact with the respective terminals of the probe card 24.

The test head 31 is held against the prober 10 by an unillustrated support mechanism. This test head 31 is electrically connected to the electrode of the unillustrated chip via the probe card 24, the probe 25, and the like. The test head 31 then inspects the electric characteristics of the chip by applying an electric current, voltage, or the like to the chip.

### <Configuration of Probe Imaging Unit>

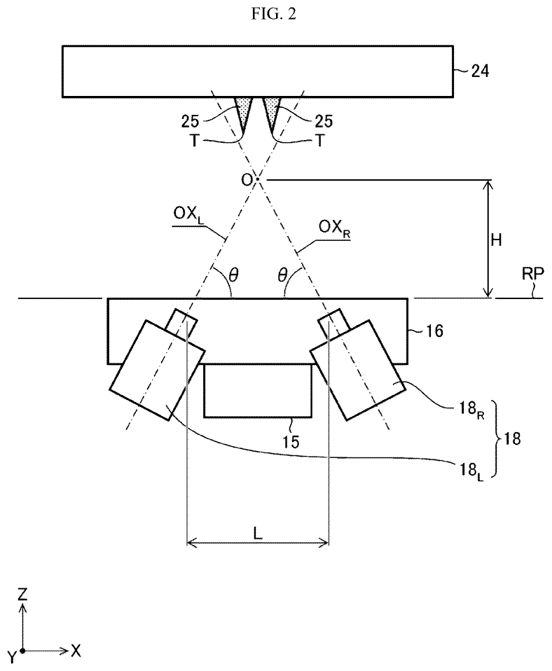

Next, the configuration of the probe imaging unit 18 will be described using FIG. 2. As illustrated in FIG. 2, the probe imaging unit 18 includes the two cameras 18_{L} and 18_{R}. For example, the probe imaging unit 18 (the cameras 18_{L} and 18_{R}) is installed near the wafer chuck 16. The probe imaging unit 18 is fixed to an unillustrated imaging unit support member, and is supported on the X stage 14 by this imaging unit support member. Therefore, the probe imaging unit 18 is configured to be movable in the XY-axis direction by the Y stage 13 and the X stage 14. Note that the imaging unit support member may support the probe imaging unit 18 such that it can be lifted and lowered in the Z-axis direction.

The cameras 18_{L} and 18_{R} each take an image of the probe 25. The cameras 18_{L} and 18_{R} have basically the same configuration, and preferably each include a telecentric optical system. In a camera including the telecentric optical system, the size of a subject in a taken image is almost independent of the distance from the camera to the subject and is nearly constant. Therefore, when the cameras 18_{L} and 18_{R} include the telecentric optical system, the probe position detector 27 can detect the position of the tip T of the probe 25 in a real space with relatively easier operations than cameras including a non-telecentric optical system based on the position of the tip T of the probe 25 on the images.

The cameras 18_{L} and 18_{R} preferably have a wider field of view and a deeper depth of focus for each camera than probe position detection cameras used in conventional probers.

Note that the cameras 18_{L} and 18_{R} may include a both-side telecentric optical system or include an object-side telecentric optical system.

The two cameras 18_{L} and 18_{R} are spaced apart from each other in the X-axis direction so as to face the probe 25. Note that the distance between the cameras 18_{L} and 18_{R} in the X-axis direction is referred to as an imaging baseline length L.

In FIG. 2, the single-dotted lines indicate an imaging optical axis (hereinafter referred to simply as the optical axis) OX_{L} of the camera 18_{L} and an optical axis OX_{R} of the camera 18_{R}. The optical axis OX_{L} and the optical axis OX_{R} lie on a plane parallel to the XZ plane, and are each inclined in the X-axis direction with respect to the Z axis. That is, the optical axis OX_{L} and the optical axis OX_{R} are not inclined in the Y-axis direction with respect to the Z axis, and are inclined in the direction facing each other and intersect each other on the side where the probe 25 is present on the plane parallel to the XZ plane.

More specifically, when viewed from the Y-axis direction as illustrated in FIG. 2, the optical axis OX_{L} of the left camera 18_{L} and the optical axis OX_{R} of the right camera 18_{R} are inclined in opposite directions at the same angle as each other in the X-axis direction with respect to the Z axis. In other words, the optical axis OX_{L} of the left camera 18_{L} is inclined at an acute-angle side inclination angle of θ (°) with respect to the X-axis direction, and the optical axis OX_{R} of the right camera 18_{R} is inclined at an acute-angle side inclination angle of 0 (°) with respect to the X-axis direction.

Since the two cameras 18_{L} and 18_{R} are oriented toward the probe 25 inclined in opposite directions at the same angle in the X-axis direction with respect to the Z axis, the optical axis OX_{L} and the optical axis OX_{R} intersect each other at an intersection point O on the plane parallel to the XZ plane. An imaging reference plane RP (also called the “imaging baseline”) of the camera 18_{L} and the camera 18_{R} is a plane parallel to the XY plane, and the distance (height) in the Z-axis direction from the imaging reference plane RP to the intersection point O is defined as an imaging distance H.

Note that the imaging baseline length L, the inclination angle θ, and the imaging distance H of the cameras 18_{L} and 18_{R} are known and are stored in advance as camera information in the memory in the controller 17 of the prober 10. The position of the intersection point O can be calculated from the camera information stored in the memory in the controller 17.

In FIG. 2, as an example, the imaging reference plane RP of the cameras 18_{L} and 18_{R} is set at a position that roughly matches the upper surface of the wafer chuck 16, but it is not intended to limit the position of the imaging reference plane RP of the cameras 18_{L} and 18_{R} to the example illustrated in FIG. 2.

Note that the imaging baseline length L and the imaging distance H may be determined, for example, from standards such as reticle marks or beams provided on the cameras 18_{L} and 18_{R}.

### <Principle of Detecting Probe Position>

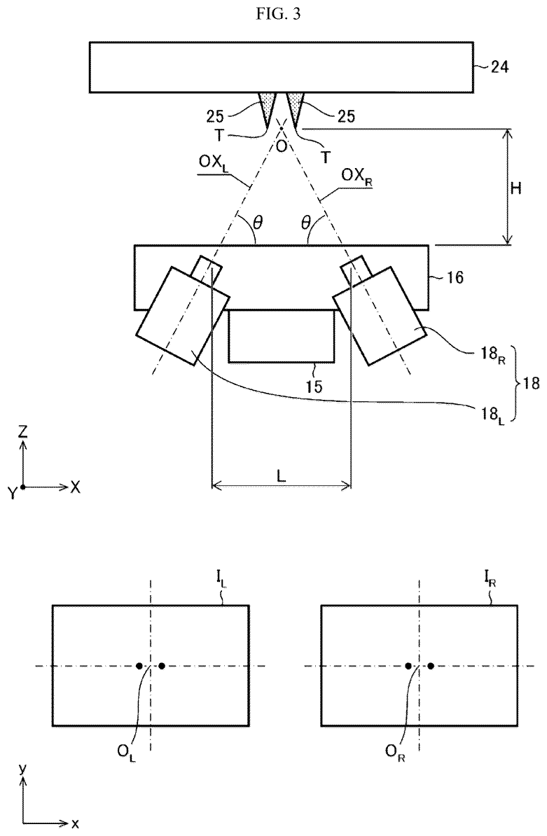

Next, the principle of detecting the position of the tip of the probe will be described using FIG. 3 to FIG. 7. The upper figures of FIG. 3 to FIG. 7 are each a figure illustrating the positional relation between the tip T of the probe 25 and the intersection point O. The lower figures of FIG. 3 to FIG. 7 each illustrate the position of the tip T of the probe 25 in the images taken by the respective cameras 18_{L} and 18_{R} in the positional relation illustrated in the upper figure of each figure. Note that for convenience of description, in the upper figures of FIG. 3 to FIG. 7, the central position of the tips T of the two probes 25 will be simply abbreviated as the position of the tip T of the probe 25 below.

In the lower figures of FIG. 3 to FIG. 7, the left figure illustrates the field of view of the camera 18_{L} and corresponds to an image I_{L} taken by the camera 18_{L} (hereinafter abbreviated as the left image). The right figure illustrates the field of view of the camera 18_{R} and corresponds to an image I_{R} taken by the camera 18_{R} (hereafter abbreviated as the right image). For simplicity, the fields of view of the cameras 18_{L} and 18_{R} and the images I_{L} and I_{R} to be taken will not be distinguished from each other and described using the same reference signs below.

In the images I_{L} and I_{R}, the direction parallel to the Y-axis direction in the real space is defined as a y-axis direction, and the direction perpendicular to the y-axis direction is defined as an x-axis direction. In the images I_{L} and I_{R} in FIG. 3 to FIG. 7, the black circles indicate the tips T of the two probes 25, and the intersection points of the dotted lines indicate field-of-view centers O_{L} and O_{R}, which correspond to the origin in the xy plane.

In the upper figure of FIG. 3, the position of the tip T of the probe 25 matches the intersection point O in the real space (the XYZ space). In this case, since the tip T of the probe 25 is imaged at the position of the field-of-view centers O_{L} and O_{R} in the left image I_{L} and the right image I_{R} illustrated in the lower part of FIG. 3, the left image I_{L} and the right image I_{R} are almost identical.

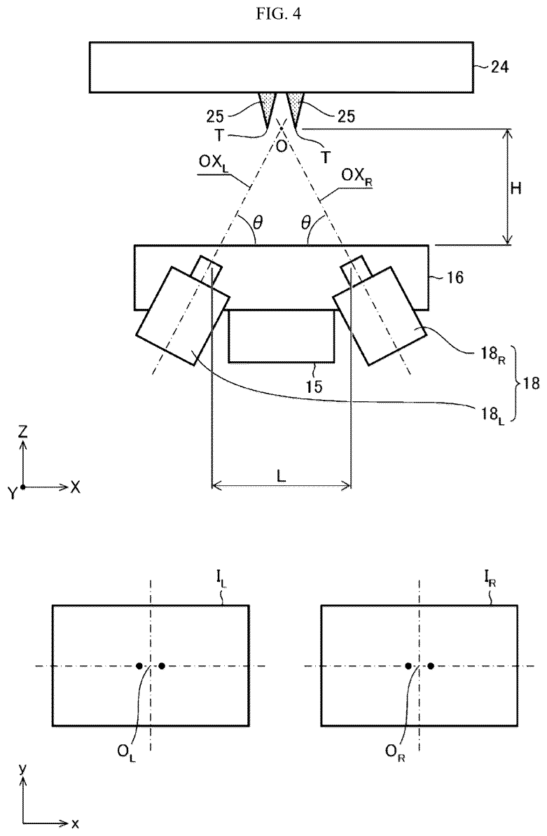

In the upper figure of FIG. 4, the position of the tip T of the probe 25 in the XY-axis direction matches the intersection point O in the real space, but the position in the Z-axis direction is lower than the intersection point O (that is, the distance between the tip T of the probe 25 and the cameras 18_{L} and 18_{R} in the Z-axis direction is shorter than the imaging distance H). In this case, as illustrated in the lower part of FIG. 4, in the left image I_{L}, the tip T of the probe 25 is positioned to the right of the field-of-view center O_{L} in the x-axis direction (in the direction indicated by the arrow A1), and in the right image I_{R}, the tip T of the probe 25 is positioned to the left of the field-of-view center O_{R} in the x-axis direction (in the direction indicated by the arrow A2).

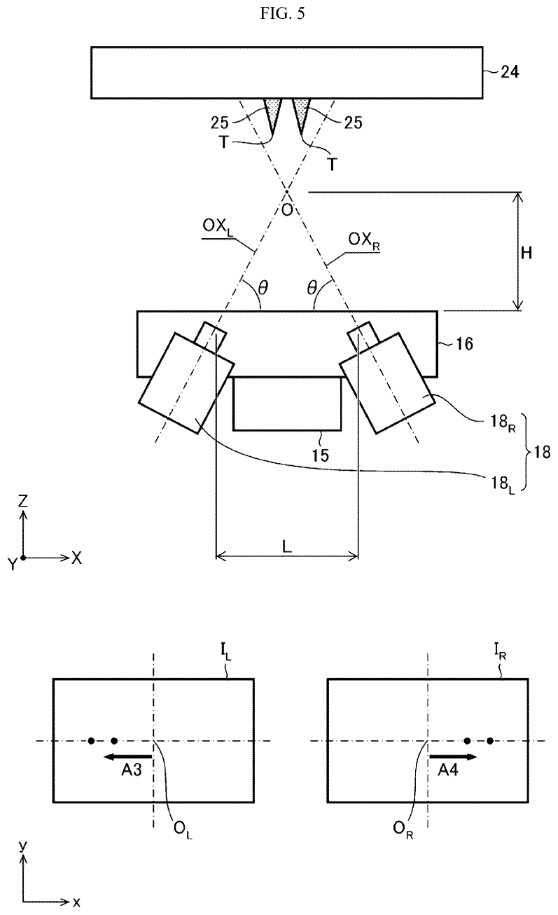

In the upper figure of FIG. 5, the position of the tip T of the probe 25 in the XY-axis direction matches the intersection point O in the real space, but the position in the Z-axis direction is higher than the intersection point O (that is, the distance between the tip T of the probe 25 and the cameras 18_{L} and 18_{R} in the Z-axis direction is longer than the imaging distance H). In this case, contrary to the case illustrated in FIG. 4, as illustrated in the lower part of FIG. 5, in the left image I_{L}, the tip T of the probe 25 is positioned to the left of the field-of-view center O_{L} in the x-axis direction (in the direction indicated by the arrow A3), and in the right image I_{R}, the tip T of the probe 25 is positioned to the right of the field-of-view center O_{R} in the x-axis direction (in the direction indicated by the arrow A4).

Thus, when the position of the tip T of the probe 25 in the XY-axis direction matches the intersection point O, but the position in the Z-axis direction is different from the position of the intersection point O, in the real space, the tip T of the probe 25 is positioned away from the field-of-view centers O_{L} and O_{R} in the x-axis direction in the left image I_{L} and the right image I_{R}, and the position of the tip T of the probe 25 in the left image I_{L} and the position of the tip T of the probe 25 in the right image I_{R} are positions opposite to each other across the field-of-view centers O_{L} and O_{R}. The distance and direction from the field-of-view centers O_{L} to the tip T of the probe 25 in the left image I_{L} and the distance and direction from O_{R} to the tip T of the probe 25 in the right image I_{R} vary in accordance with the positional relation between the position of the tip T of the probe 25 in the Z-axis direction and the position of the intersection point O in the real space.

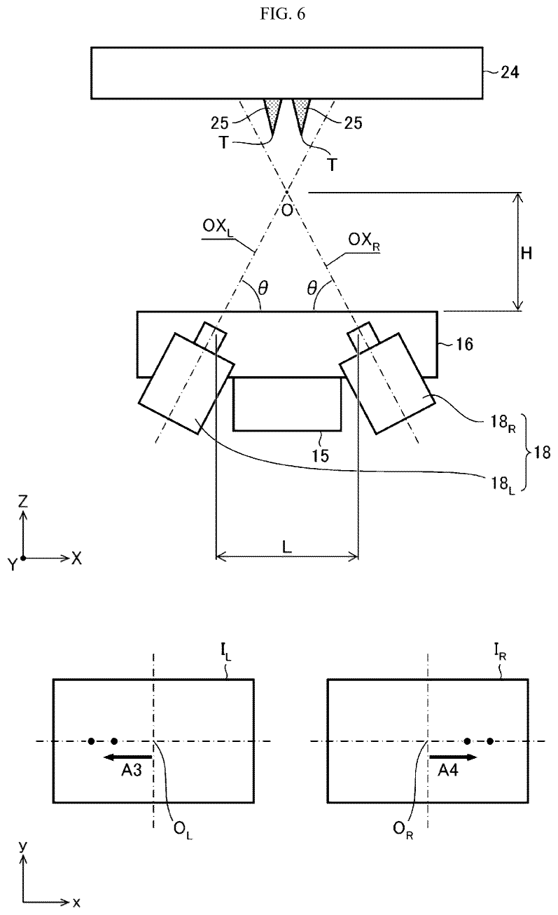

In the upper figure of FIG. 6, the position of the tip T of the probe 25 in the YZ-axis direction matches the intersection point O, but the position in the X-axis direction is to the right of the intersection point O (closer to the camera 18_{R}), in the real space. In this case, as illustrated in the lower part of FIG. 6, in both the left image I_{L} and the right image I_{R}, the tip T of the probe 25 is positioned to the right of the field-of-view centers O_{L} and O_{R} in the x-axis direction (in the direction indicated by the arrows A5 and A6).

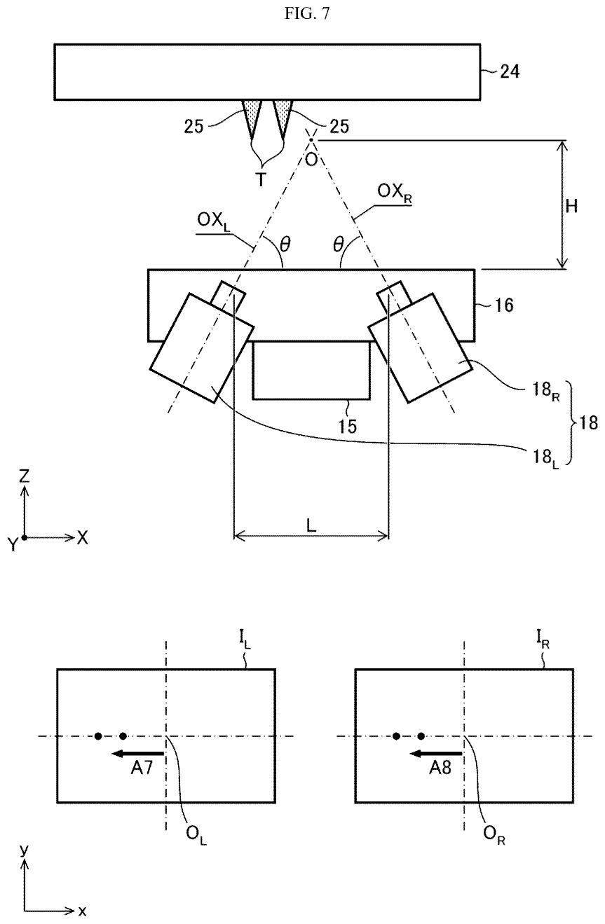

In the upper figure of FIG. 7, the position of the tip T of the probe 25 in the YZ-axis direction matches the intersection point O, but the position in the X-axis direction is to the left of the intersection point O (closer to the camera 18_{L}), in the real space. In this case, as illustrated in the lower part of FIG. 7, in both the left image I_{L} and the right image I_{R}, the tip T of the probe 25 is positioned to the left of the field-of-view centers O_{L} and O_{R} in the x-axis direction (in the direction indicated by the arrows A7 and A8).

Thus, when the position of the tip T of the probe 25 in the YZ-axis direction matches the intersection point O, but the position in the X-axis direction is different from the position of the intersection point O, in the real space, the tip T of the probe 25 is positioned away from the field-of-view centers O_{L} and O_{R} in the x-axis direction in the left image I_{L} and the right image I_{R}, and the position of the tip T of the probe 25 in the left image I_{L} and the position of the tip T of the probe 25 in the right image I_{R} are positions on the same side as each other with respect to the field-of-view centers O_{L} and O_{R}. The distance and direction from the field-of-view centers O_{L} to the tip T of the probe 25 in the left image I_{L} and the distance and direction from O_{R} to the tip T of the probe 25 in the right image I_{R} vary in accordance with the positional relation between the position of the tip T of the probe 25 in the X-axis direction and the position of the intersection point O in the real space.

Although not illustrated in the figures, when the position of the tip T of the probe 25 in the Y-axis direction is different from the position of the intersection point O in the real space, the tip T of the probe 25 is positioned away from the field-of-view centers O_{L} and O_{R} in the y-axis direction in the left image I_{L} and the right image I_{R}, and the position of the tip T of the probe 25 in the left image I_{L} and the position of the tip T of the probe 25 in the right image I_{R} are positions on the same side as each other with respect to the field-of-view centers O_{L} and O_{R}. The distance and direction from the field-of-view centers O_{L} to the tip T of the probe 25 in the left image I_{L} and the distance and direction from O_{R} to the tip T of the probe 25 in the right image I_{R} vary in accordance with the positional relation between the position of the tip T of the probe 25 in the Y-axis direction and the position of the intersection point O in the real space.

Thus, as illustrated in FIG. 3 to FIG. 7, the position of the tip T of the probe 25 relative to the intersection point O can be determined from the images I_{L} and I_{R} taken by the two cameras 18_{L} and 18_{R}. The probe position detector 27 uses this principle to geometrically detect the position of the tip T of the probe 25 from the images I_{L} and I_{R}.

### <Method for Detecting Probe Position>

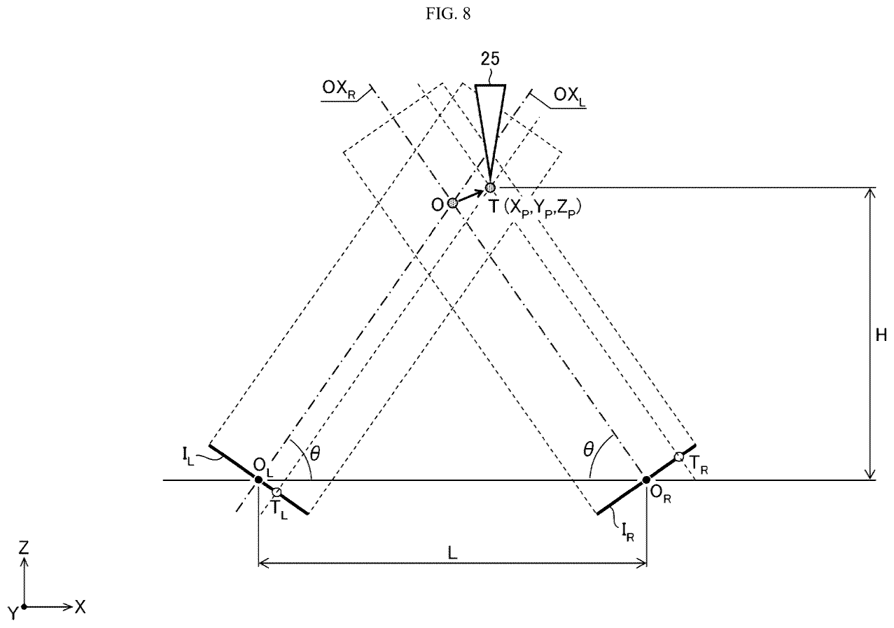

A method for detecting the position of the tip T of the probe 25 by the probe position detector 27 will be described below specifically using FIG. 8 to FIG. 10.

FIG. 8 illustrates an example of the positional relation between the tip T of one probe 25 and the optical axes OX_{L} and OX_{R} of the cameras 18_{L} and 18_{R}. In FIG. 8, the single-dotted lines indicate the optical axis OX_{L} and the optical axis OX_{R}. The thick solid lines indicate the fields of view (corresponding to the images) I_{L} and I_{R} of the cameras 18_{L} and 18_{R}, respectively. Note that when imaging the tip T of the probe 25 by the cameras 18_{L} and 18_{R}, it is assumed that the focus of the cameras 18_{L} and 18_{R} is adjusted so as to roughly match the tip T of the probe 25. If the misalignment between the focus of the cameras 18_{L} and 18_{R} and the tip T of the probe 25 exceeds a certain distance (the depth of focus of each of the cameras 18_{L} and 18_{R}), a process of making the cameras 18_{L} and 18_{R} roughly focused on the tip T of the probe 25 (a focus adjustment step) is performed.

For the sake of description, it is assumed here that the imaging magnification of the cameras 18_{L} and 18_{R} is equal (1×), and the distance on each of the images taken by the cameras 18_{L} and 18_{R} is equal to the distance in the real space. If the imaging magnification of the cameras 18_{L} and 18_{R} is other than equal, the distance on each of the images taken by the cameras 18_{L} and 18_{R} may be converted to the distance in the real space and calculated based on the imaging magnification of the cameras 18_{L} and 18_{R}.

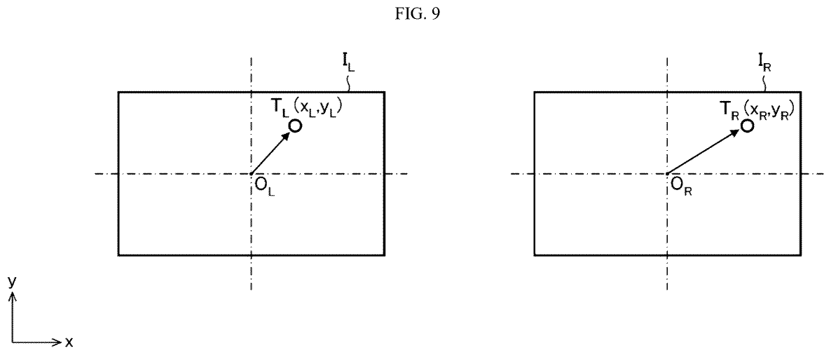

Since the fields of view I_{L} and I_{R} are planes perpendicular to the XZ plane, the fields of view I_{L} and I_{R} are represented as the thick solid lines in FIG. 8. In reality, the fields of view I_{L} and I_{R} are planes as illustrated in FIG. 9. An intersection point O_{L} between the field of view I_{L} and the optical axis OX_{L} indicates the field-of-view center of the camera 18_{L}, and an intersection point O_{R} between the field of view I_{R} and the optical axis OX_{R} indicates the field-of-view center of the camera 18_{R}.

In FIG. 8, with the intersection point O in the real space as the origin, the spatial coordinates of the tip T of the probe 25 are defined as T (X_{P}, Y_{P}, Z_{P}) (the coordinates of the tip T relative to the intersection point O). As illustrated in FIG. 8, the position obtained by projecting the position of the tip T of the probe 25 onto the field of view I_{L} of the camera 18_{L} along the optical axis OX_{L} corresponds to a position TL of the tip T of the probe 25 in the left image I_{L} (indicated by the white circle in FIG. 8). Similarly, the position obtained by projecting the position of the tip T of the probe 25 onto the field of view I_{R} of the camera 18_{R} along the optical axis OX_{R} corresponds to a position TR of the tip T of the probe 25 in the right image I_{R} taken by the camera 18_{R} (indicated by the white circle in FIG. 8).

FIG. 9 illustrates the fields of view I_{L} and I_{R} of the respective cameras in the positional relation illustrated in FIG. 8. In FIG. 9, the left figure illustrates the field of view (the image) I_{L} of the camera 18_{L}, and the right figure illustrates the field of view (the image) I_{R} of the camera 18_{R}. In the fields of view I_{L} and I_{R}, the positions T_{L} and T_{R} of the tip T of the probe 25 are indicated by the white circles. In the field of view I_{L}, the coordinates of T_{L} with the field-of-view center O_{L} as the origin are defined as (x_{L},y_{L}), and in the field of view I_{R}, the coordinates of T_{R} with the field-of-view center O_{R} as the origin are defined as (x_{R},y_{R}).

In the geometric relation illustrated in FIG. 8 and FIG. 9, first, since the optical axis OX_{L} and the optical axis OX_{R} are not inclined in the Y-axis direction and are on the same plane, the Y coordinate Y_{P} of the tip T of the probe 25 in the real space corresponds to the y coordinates y_{L} and y_{R} of the positions T_{L} and T_{R} of the tip T of the probe 25 in the fields of view I_{L} and I_{R}. In other words, y_{L}=YP or y_{R}=Y_{P} holds.

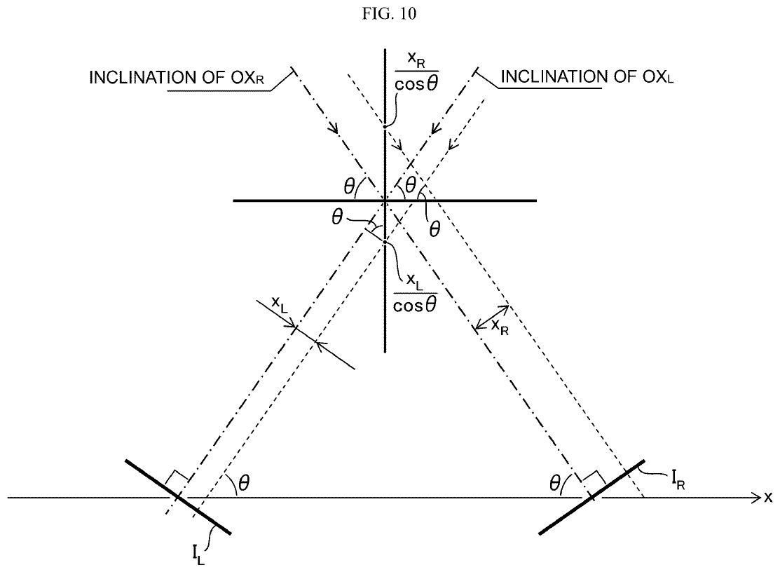

Next, geometric operations to detect the X coordinate and the Z coordinate among the spatial coordinates (X_{P}, Y_{P}, X_{P}) of the tip T of the probe 25 with the intersection point O in the real space as the origin will then be described using FIG. 10. As illustrated in FIG. 10, since the optical axis OX_{L} and the optical axis OX_{R} are each inclined by an acute-angle side inclination angle θ with respect to the X-axis direction, the following simultaneous equations consisting of Expression (1) and Expression (2) below hold for the Z coordinate Z_{P} of the tip T of the probe 25 in the real space.

$$\begin{matrix}[ Expression 1 ] & \\ {Z}_{P} = tan θ {X}_{P} - \frac{{x}_{L}}{cos θ} & ( 1 )\end{matrix}$$

$$\begin{matrix}[ Expression 2 ] & \\ {Z}_{P} = - tan θ {X}_{P} + \frac{{x}_{R}}{cos θ} & ( 2 )\end{matrix}$$

By solving these simultaneous equations, Expression (3) and Expression (4), which are calculation formulae for X_{P} and Z_{P}, can be obtained.

$$\begin{matrix}[ Expression 3 ] & \\ {X}_{P} = \frac{1}{2 sin θ} ( {x}_{L} + {x}_{R} ) & ( 3 )\end{matrix}$$

$$\begin{matrix}[ Expression 4 ] & \\ {Z}_{P} = \frac{1}{2 cos θ} ( {x}_{R} - {x}_{L} ) & ( 4 )\end{matrix}$$

By using such a method of detection, the probe position detector 27 can detect the spatial coordinates (X_{P}, Y_{P}, X_{P}) of the tip T of the probe 25 in the real space from the coordinates of the tip T of the probe 25 in the images I_{L} and I_{R} taken by the cameras 18_{L} and 18_{R}.

After the position of the tip T of the probe 25 is detected by the probe position detector 27, based on the detected position of the tip T of the probe 25, the stage movement controller 28 controls the Y stage 13, the X stage 14, and the Zθ stage 15 via the unillustrated drive mechanisms to perform relative alignment between the probe card 24 and the wafer chuck 16. After that, wafer level inspection is performed.

Since the prober according to the conventional technologies requires the focusing of the probe position detection camera to detect the tip T of the probe 25, it takes time to detect the position of the tip T of the probe 25. Especially when a camera with a shallow depth of focus is used, it takes more time for the focusing of the probe position detection camera, bringing about a reduction in throughput.

On the other hand, since the prober 10 according to the present embodiment can detect the position of the tip T of the probe 25 based on the two images I_{L} and I_{R} taken by the two cameras 18_{L} and 18_{R}, the time required for such focusing as described above can be significantly reduced. Therefore, the position of the tip T of the probe 25 can be detected more quickly than with conventional technologies. Note that when the cameras 18_{L} and 18_{R} are roughly focused on the tip T of the probe 25, the focusing of the cameras 18_{L} and 18_{R} is not necessary.

In the prober according to the conventional technologies, in order for the probe position detection camera not to come into contact with the probe 25, assuming that various types of probe cards 24 are used, it is necessary to set the distance between the probe card 24 and the probe position detection camera to an initial value with a margin (also called an initial height).

On the other hand, in the prober 10 according to the present embodiment, the cameras 18_{L} and 18_{R} need only be roughly focused on the tip T of the probe 25, and there is virtually no time required for the focusing of the cameras 18_{L} and 18_{R}, and thus even if such a margin as described above is set, the position of the tip T of the probe 25 can be quickly detected.

Furthermore, in the prober according to the conventional technologies, if the distance between the probe card 24 and the probe position detection camera is incorrectly set shorter than the initial value, the probe card 24 and the probe position detection camera may come into contact with each other during the focusing of the probe position detection camera. Conversely, if the distance between the probe card 24 and the probe position detection camera is incorrectly set longer than the initial value, even if the focusing of the camera is performed while changing the height of the probe position detection camera in small increments, the probe position detection camera will not focus easily, and it will take more time to detect the position of the tip T of the probe 25.

On the other hand, in the prober 10 according to the present embodiment, since the cameras 18_{L} and 18_{R} need only be roughly focused on the tip T of the probe 25, the margin (tolerance) for the above initial value can be expanded. Therefore, even if the distance between the probe card 24 and each of the cameras 18_{L} and 18_{R} differs from the initial value, there is no possibility of contact between the probe card 24 and the cameras 18_{L} and 18_{R}, and the problem that the time required to detect the position of the tip T of the probe 25 is prolonged is unlikely to occur.

### Effects of the Invention

In the prober 10 according to the present embodiment, the probe position detector 27 can detect the position of the tip T of the probe 25 based on the two images I_{L} and I_{R} taken by the two cameras 18_{L} and 18_{R}. Since there is virtually no time required for the focusing of the cameras 18_{L} and 18_{R} for position detection of the tip T of the probe 25, the position of the tip T of the probe 25 can be quickly detected.

In the prober 10 according to the present embodiment, since the optical axes OX_{L} and OX_{R} of the two cameras 18_{L} and 18_{R} intersect each other on the same plane, the position of the tip T of the probe 25 can be detected based on the two images I_{L} and I_{R} with relatively easy geometric operations.

In the prober 10 according to the present embodiment, since the two cameras 18_{L} and 18_{R} each have a telecentric optical system, the size of the tip T of the probe 25 in the images I_{L} and I_{R} is independent of the distance from each of the cameras 18_{L} and 18_{R} to the tip T and is almost constant. The position of the tip T of the probe 25 detected based on the images I_{L} and I_{R} can be easily converted to the actual position in the real space.

### <Others>

The prober 10 according to the present invention has been described in detail, but the present invention may of course be subject to some improvements or modifications to the extent that they do not depart from the gist of the present invention. Some modifications will be exemplified below.

The above embodiment discloses a case as a preferred case in which the optical axes OX_{L} and OX_{R} of the two cameras 18_{L} and 18_{R} are each inclined in opposite directions at the same angle as each other in the X-axis direction with respect to the Z axis, but they need not necessarily be inclined at the same angle. If the optical axis OX_{L} and the optical axis OX_{R} are inclined in opposite directions at different different angles from each other in the X-axis direction with respect to the Z axis, the inclination angle θ in Expression 1 to Expression 4 may be changed as appropriate for calculation.

The above embodiment discloses a case in which the optical axes OX_{L} and OX_{R} of the two cameras 18_{L} and 18_{R} are on the plane parallel to the XZ plane and not inclined in the Y-axis direction, but the above embodiment is not necessarily limiting, and the optical axes OX_{L} and OX_{R} of the two cameras 18_{L} and 18_{R} may be inclined in the Y-axis direction with respect to the Z axis Y. In this case, by using a known triangulation method for the method for detecting the probe position, the position of the tip T of the probe 25 can be detected.

The above embodiment discloses a case in which the cameras 18_{L} and 18_{R} are provided near the wafer chuck 16, but it is not intended to limit the positions at which the cameras 18_{L} and 18_{R} are disposed. The positions of the cameras 18_{L} and 18_{R} may be changed as appropriate in accordance with the spatial arrangement of various devices near the wafer chuck 16.

Furthermore, the cameras 18_{L} and 18_{R} of the present invention may be provided in addition to the probe position detection camera in which the optical axis of the prober is substantially parallel to the Z axis according to the conventional technologies. In this case, avoidance of a collision between the probe and the probe position detection camera and a reduction in the time for focusing can be achieved while maintaining the accuracy of the probe position detection camera of the conventional technologies.

In the above embodiment, the two cameras 18_{L} and 18_{R} are provided, but this is not limiting, and three or more cameras may be provided.

### REFERENCE SIGNS LIST

1 WAFER TEST SYSTEM
10 PROBER
11 SUPPORT BASE
12 BASE
13 Y STAGE
14 X STAGE
15 Zθ STAGE
16 WAFER CHUCK
17 CONTROLLER
18 PROBE IMAGING UNIT
18_{L}, 18_{R} CAMERA
19 WAFER ALIGNMENT CAMERA
22 HEAD STAGE
23 CARD HOLDER
24 PROBE CARD
25 PROBE
26 TESTER COMMUNICATION CONTROLLER
27 PROBE POSITION DETECTOR
28 STAGE MOVEMENT CONTROLLER
30 TESTER
31 TEST HEAD
32 CONTACT RING
A1, A2, A3, A4, A5, A6, A7, A8 ARROW
I_{L}, I_{R} IMAGE (FIELD OF VIEW)
H IMAGING DISTANCE
L IMAGING BASELINE LENGTH
O INTERSECTION POINT
O_{L}, O_{R} FIELD-OF-VIEW CENTER
OC_{L}, OX_{R} OPTICAL AXIS
RP IMAGING REFERENCE PLANE
T, T_{L}, T_{R} TIP
W WAFER
θ INCLINATION ANGLE

1. A prober comprising:
a wafer chuck that holds a wafer;
a probe card that has a probe on a surface facing the wafer chuck;
a movement mechanism that moves the wafer chuck relative to the probe card;
a probe imaging unit that has two cameras and takes images of the probe by the two cameras; and
a probe position detector that detects a position of a tip of the probe based on two images taken by the two cameras.

2. The prober according to claim 1, wherein imaging optical axes of the two cameras intersect each other.

3. The prober according to claim 2, wherein the two cameras are each a camera configured with a telecentric optical system.

4. The prober according to claim 1, wherein the movement mechanism moves the probe imaging unit relative to the probe card.

5. The prober according to claim 2, wherein the movement mechanism moves the probe imaging unit relative to the probe card.

6. The prober according to claim 3, wherein the movement mechanism moves the probe imaging unit relative to the probe card.
